(19) United States
(12) Patent Application Publication
(10) Pub. No.: US 2025/0081475 A1
(43) Pub. Date: Mar. 6, 2025

(54) NON-VOLATILE MEMORY INCLUDING A DEPLETION LAYER WITH A SUPERLATTICE AND RELATED METHODS

(71) Applicant: Atomera Incorporated, Los Gatos, CA (US)

(72) Inventors: HIDEKI TAKEUCHI, SAN JOSE, CA (US); NYLES WYNN CODY, TEMPE, AZ (US); ABHISHEK RAOL, SAN JOSE, CA (US)

(21) Appl. No.: 18/821,271

(22) Filed: Aug. 30, 2024

Related U.S. Application Data
(60) Provisional application No. 63/580,016, filed on Sep. 1, 2023.

(51) Int. Cl. H10B 99/00; H01L 29/15

(52) U.S. Cl. CPC H10B 99/22; H10D 62/8162

(57) ABSTRACT

A memory device may include an array of memory cells on a semiconductor substrate. Each memory cell may include a first well on the semiconductor substrate having a first conductivity type, a second well adjacent the first well and having a second conductivity type and defining a depletion layer with the first well, and a superlattice within the depletion layer. The superlattice may include stacked groups of layers, with each group of layers comprising stacked base semiconductor monolayers defining a base semiconductor portion, and a non-semiconductor monolayer(s) constrained within a crystal lattice of adjacent base semiconductor portions. Trap source atoms may also be within the stacked groups of layers. Each memory cell may further include spaced apart source and drain regions adjacent the second well and defining a channel therebetween, and a gate overlying the channel.

### CROSS-REFERENCE TO RELATED APPLICATIONS

This application claims the benefit of U.S. provisional app. No. 63/580,016 filed Sep. 1, 2023, which is hereby incorporated herein in its entirety by reference.

### TECHNICAL FIELD

The present disclosure generally relates to semiconductor devices, and, more particularly, to semiconductor memory devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A memory device may include a semiconductor substrate and an array of memory cells on a semiconductor substrate. Each memory cell may include a first well on the semiconductor substrate having a first conductivity type, a second well adjacent the first well and having a second conductivity type and defining a depletion layer with the first well, and a superlattice within the depletion layer. The superlattice may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions. A plurality of trap source atoms may also be within the plurality of stacked groups of layers, with the trap source atoms being different than semiconductor atoms of the base semiconductor monolayers and non-semiconductor atoms of the at least one non-semiconductor monolayer. Each memory cell may further include spaced apart source and drain regions adjacent the second well and defining a channel therebetween, and a gate overlying the channel.

In one embodiment, each memory cell may further include a body contact region coupled with the first well. In example implementations, the at least one non-semiconductor monolayer may comprise oxygen, and the base semiconductor layers may comprise silicon. In one embodiment, the memory cells may comprise non-volatile memory cells. The memory device may further include respective shallow trench isolation (STI) regions adjacent the source and drain regions and extending into the first well. Furthermore, the trap source atoms may comprise at least one of fluorine, sulfur, and selenium. The memory device may also include plurality of word lines and bit lines connecting the plurality of memory cells.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross-sectional diagram of an example implementation of a nonvolatile memory cell including a superlattice which enables charge trapping.

FIG. 5A is a top plan view of a nonvolatile memory device incorporating the memory cell of FIG. 4 shown during programming, and FIGS. 5B-5D are schematic cross-sectional diagrams of different memory cells within the memory device of FIG. 5A shown during programming of the memory cell of FIG. 5B.

FIG. 6 is a graph of current vs. voltage for an example programming operation of the memory cell of FIG. 5B.

FIG. 7A is a top plan view of the nonvolatile memory device of FIG. 5A shown during erasing, and FIGS. 7B-7D are schematic cross-sectional diagrams of different memory cells within the memory device of FIG. 5A shown during erasing of the memory cell of FIG. 5B.

FIG. 8 is a graph of current vs. voltage for an example erasing operation of the memory cell of FIG. 5B.

FIG. 9 is a schematic cross-sectional diagram of the memory cell of FIG. 5B shown during reading in an example embodiment.

FIGS. 10A-10C are a series of schematic cross-sectional diagrams illustrating a method of making the memory cell of FIG. 4 in accordance with an example embodiment.

FIGS. 11A-11C are a series of schematic cross-sectional diagrams illustrating a method of making the memory cell of FIG. 4 in accordance with another example embodiment.

FIG. 12A is a graph illustrating an example doping profile under the channel for the memory cell of FIG. 4.

FIG. 12B is a graph illustrating an example doping profile under the source/drain regions for the memory cell of FIG. 4.

FIG. 12C is a graph illustrating drain leakage characteristics for the memory cell of FIG. 4 in an example embodiment.

FIG. 12D is a graph illustrating drain breakdown voltage vs. NWEL and PWELL dosages for the memory cell of FIG. 4 in example implementations.

FIG. 13 is a transmission electron microscopy (TEM) image of an example implementation of the depletion layer of the memory cell of FIG. 4 with representative dimensions.

FIGS. 14A-14D are a series of schematic cross-sectional diagrams illustrating another memory cell including a depletion layer with traps, and associated fabrication steps, in an example implementation.

FIG. 15 is a graph of atomic concentration vs depth for an MST-C superlattice which may be used in the fabrication of the memory cell of FIG. 14D.

FIG. 16 is a TEM image of an MST-C superlattice which may be used in the fabrication of the memory cell of FIG. 14D.

FIG. 17 is a TEM image of the SiC superlattice of FIG. 16 after annealing to form nanocrystals.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂ . Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

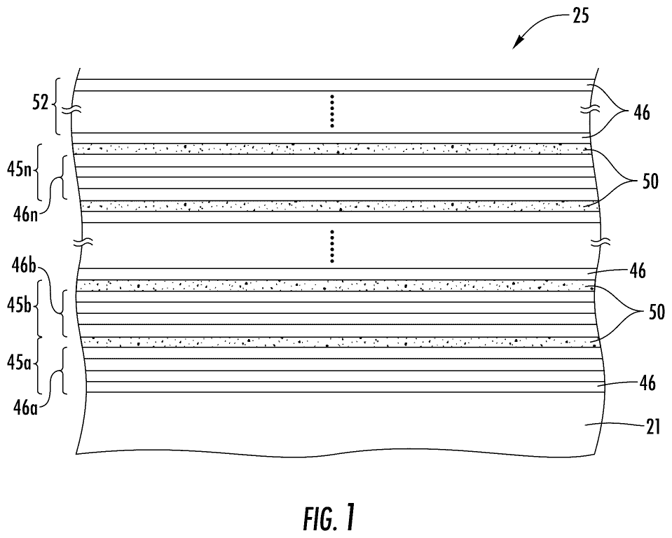

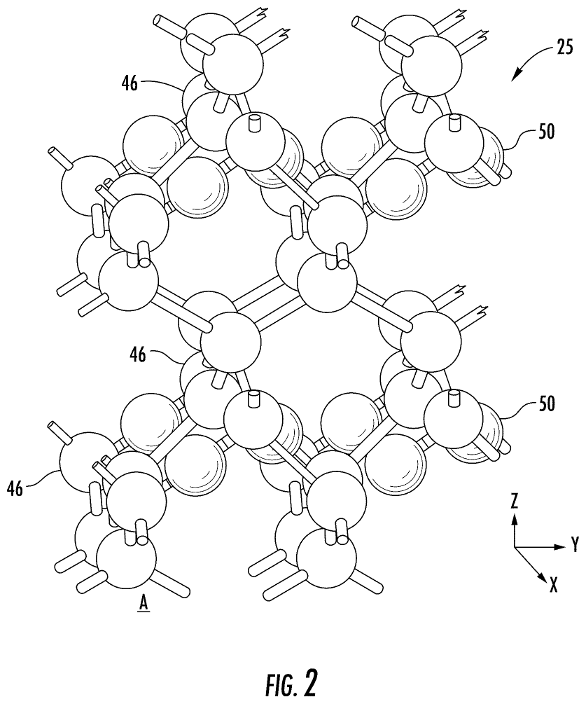

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

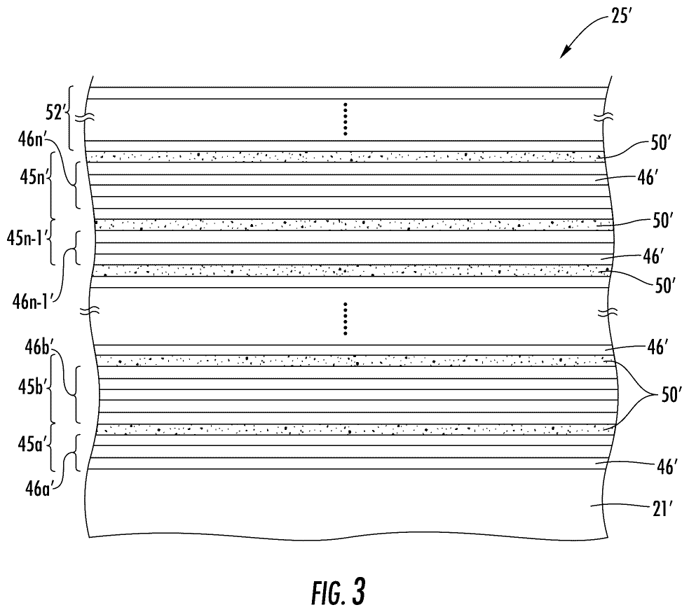

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

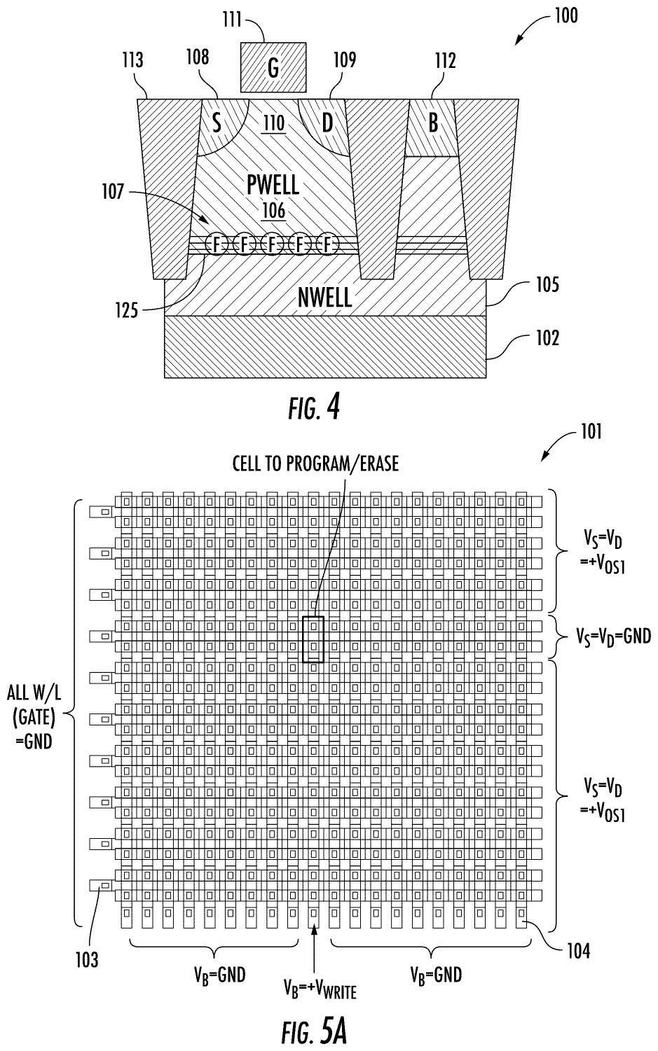

Turning now to FIGS. 4 and 5A, an example nonvolatile random access memory (NVRAM) cell 100 and associated NVRAM device 101 are first described. Generally speaking, in the memory cell 100 an NWELL/PWELL is enclosed and isolated within a PWELL/NWELL, with a depletion layer at the junction between the two wells which leverages an MST film to enable charge trapping. More particularly, in the memory device 101 a plurality of memory cells 100 are formed on a semiconductor substrate 102 and electrically coupled in an array by word lines 103 and bit lines 104. Each memory cell 100 illustratively includes a first well 105 on the semiconductor substrate 102 having a first conductivity type, which in the example of FIG. 4 is n-type defining an NWELL (although this could be a PWELL in other embodiments).

A second well 106 is adjacent (here above) the first well 105 and has a second conductivity type (here p-type defining a PWELL, although this could be an NWELL in other embodiments). More particularly, in the illustrated configuration the second well 106 is enclosed by the first well 105. Moreover, the second well 106 defines a depletion layer 107 with the first well 105. A superlattice 125, such as those described above, is located within the depletion layer 107. More particularly, trap source atoms (e.g., fluorine, sulfur, or selenium) are also located within the stacked groups of layers of the superlattice 125. Each memory cell 100 further illustratively includes spaced apart source and drain regions 108, 109 adjacent (here within) the second well 106 and defining a channel 110 therebetween. A gate 111 (which may include a gate dielectric and a gate electrode, not shown) overlies the channel 110 on the PWELL 106. The memory device 100 also illustratively includes a body contact region 112 coupled with the first well 105, and shallow trench isolation (STI) regions 113 adjacent the source, drain, and body regions 108, 109, 112 and extending into the first well below the superlattice 125 as shown.

The MST superlattice film 125 provides a technical advantage of allowing for embedded traps in the depletion layer 107 to capture electrons/holes to facilitate read and erase operations. The depletion layer 107 is designed to be located above the bottom of the STI regions 113, providing a further technical advantage of preventing write and erase disturbances to other cells 100 during program and erase operations.

Programming of a given memory cell within the memory device 101 is now described with reference to FIGS. 5B-5D. The cell 100 being programmed is shown in FIG. 5B, a non-programmed cell in the same column as the cell being programmed is shown in FIG. 5C, and a non-programmed cell from a different column than the programmed cell is shown in FIG. 5D. The corresponding voltage levels that are applied to the source 108, drain 109, gate 111, and body 112 contacts to perform each of these operations are shown in 5A-5D. Generally speaking, a high reverse body bias is applied by coupling the source 108, drain 109, and gate 111 contacts to ground GND, and coupling the body 112 contact to a write voltage (+V_{WRITE}). This induces an avalanche breakdown at the depletion region 107 (i.e., the PWELL/NWELL junction), as shown in FIG. 5B. More particularly, this causes the embedded traps in the depletion layer 107 to capture generated electrons and thereby program the desired cell 100.

To avoid disturbing the programming of the other cells 100 in the same and different columns, an offset voltage (+V_{OS1}) is applied to the source 108 and drain 109 contacts of the other cells. The gate 111 and body 112 contacts of the other memory cells 100 are coupled to ground GND, except that the body contacts in the same column as the programmed cell have their body contacts also coupled to the write voltage V_{WRITE}. Referring additionally to graph 120 of FIG. 6, V_{WRITE} and V_{OS1} may be determined by diode I-V characteristics and can be set, for example, at V_{WRITE}=5V and V_{OS1}=0.5V, although other suitable values may be used in different embodiments.

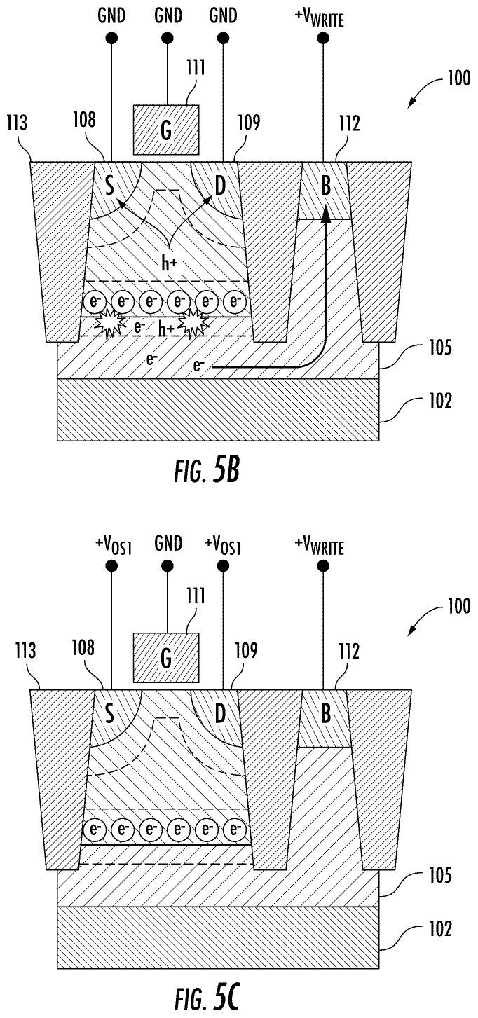

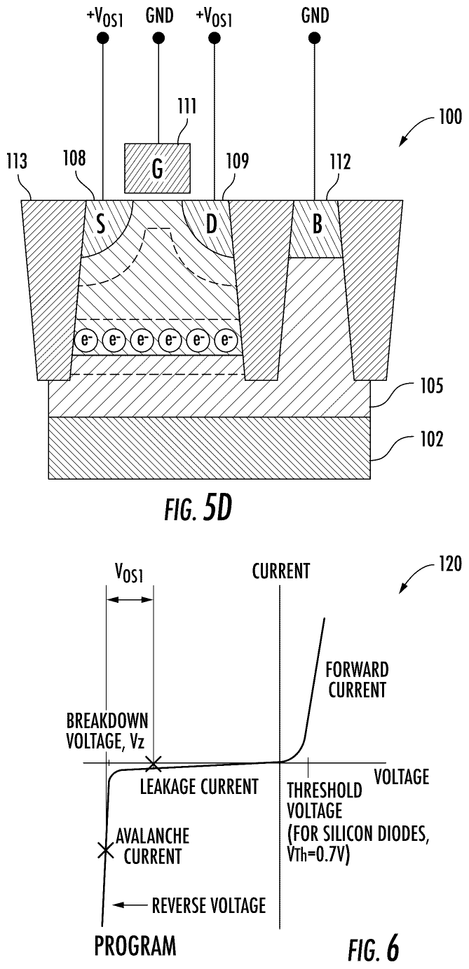

Turning to FIGS. 7A-7D, erasing of the same memory cell is now described. This is accomplished by applying forward body bias to inject holes to the depletion region 107 (trap layer), by applying V_{ERASE} to the body contact 112 as seen in FIG. 7B. The injected holes recombine with trap electrons to erase the previous program state. Disturbing of the programmed values in other cells 100 may be prevented by applying an appropriate offset voltage (V_{OS2}) to the source 108 and drain 109 contacts of cells in the same column while V_{ERASE} is applied to the body contact 112 (see FIG. 7C), and V_{OS2} is applied to the source 108, drain 109, and body 112 contacts for cells in other columns. Referring additionally to the graph 130 of FIG. 8, V_{ERASE} and V_{OS2} may also be determined by the diode I-V characteristics curve and can be set, for example, at V_{ERASE}=1V and V_{OS2}=0.8V, although other suitable values may be used in different embodiments.

Referring to FIG. 9, an example read operation of a memory cell 100 is shown. Trapped electrons increase MOSFET V_{T} due to body effect. The current program state may be read through regular MOSFET operation, that is, by applying gate and drain bias to the cell transistor as shown. In the present example, the source 108 contact is connected to ground GND, the gate 111 contact is connected to a read voltage V_{READ}, the drain 109 contact is connected to V_{DD}, and the base contact 112 is also connected to ground GND.

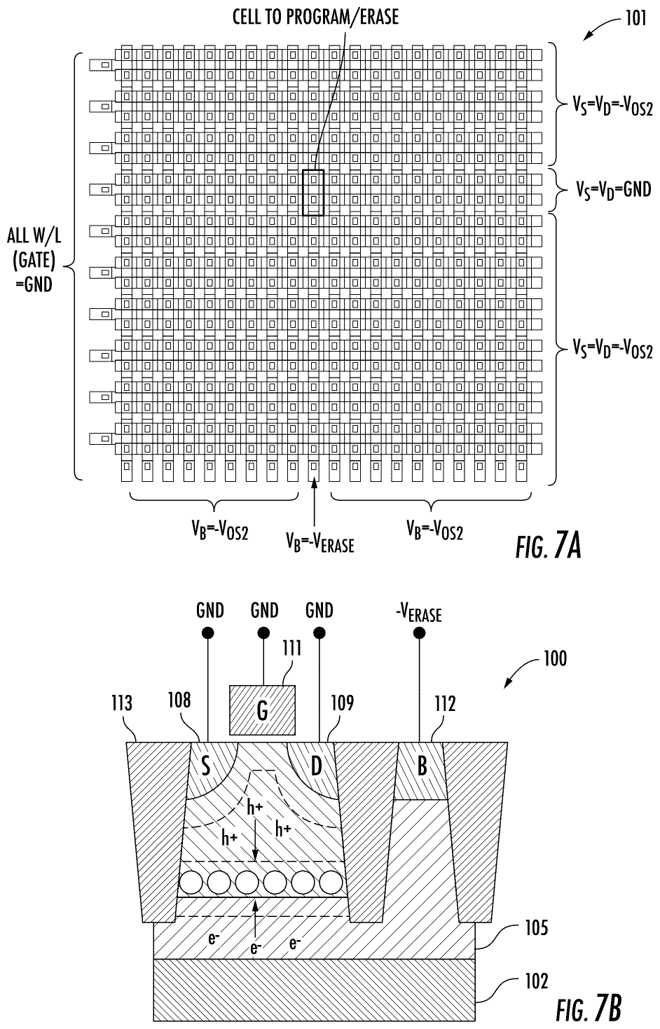

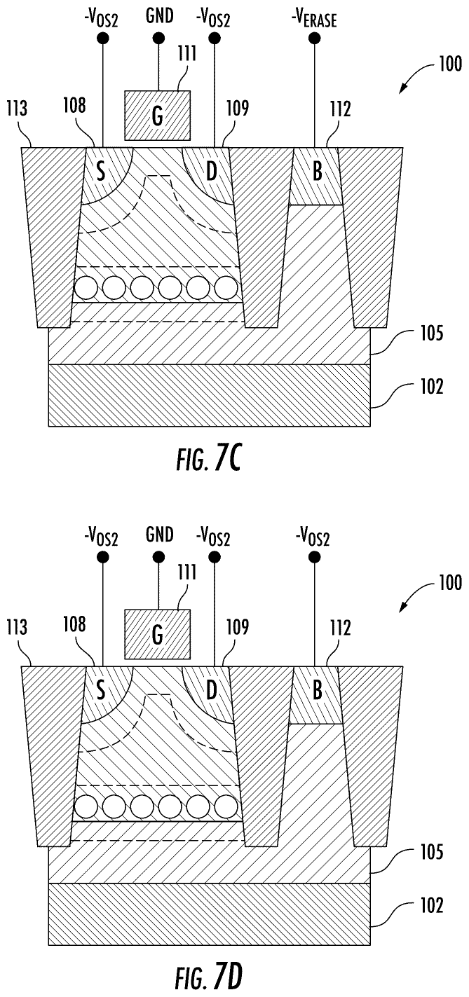

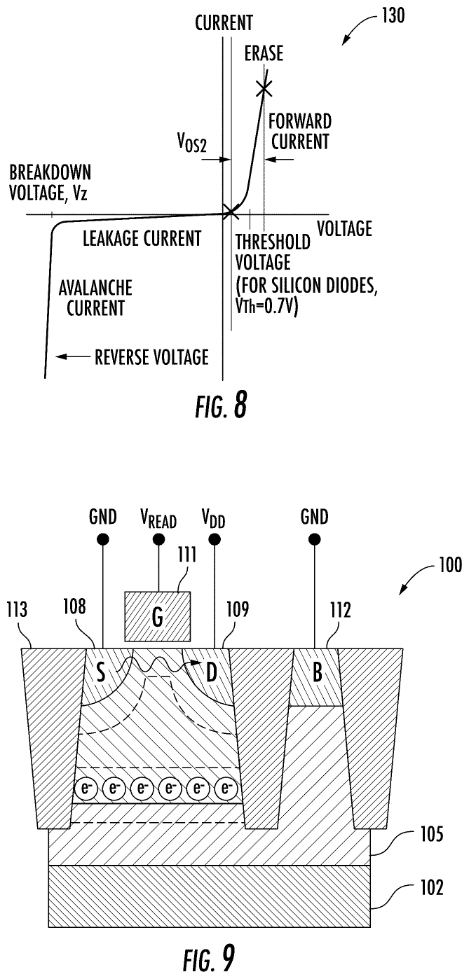

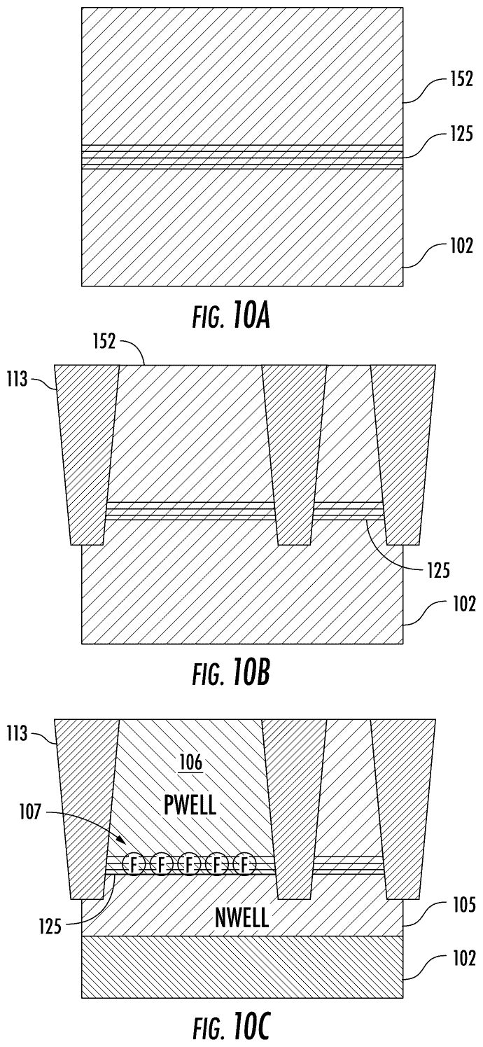

Turning now to FIGS. 10A-10C, an example method for fabricating the memory cell 100 is described. In the illustrated example, an MST-O (Si/O) film 125 is formed on the substrate 102 (e.g., a silicon substrate). In the present embodiment, the MST-O layer 125 is deposited via a blanket epitaxial growth across the entire substrate 102 before the STI module. A relatively thick cap layer 152 may be epitaxially formed on the MST-O film 125, followed by the STI module to define the STI regions 113. The NWELL, trap source atoms (fluorine in the present example), and PWELL dopants may then be introduced, in that order, confining atomic fluorine in the depletion region 107 (FIG. 10C). By way of example, the fluorine may be implanted using ion implantation. A similar process for fabricating the memory cell 100 is shown in FIGS. 11A-11C, but here the MST-O film 125 is fabricated through selective epitaxial growth in silicon recesses after the STI module, as shown. The NWELL, fluorine, and PWELL implants may be performed in the same manner described above (FIG. 11C).

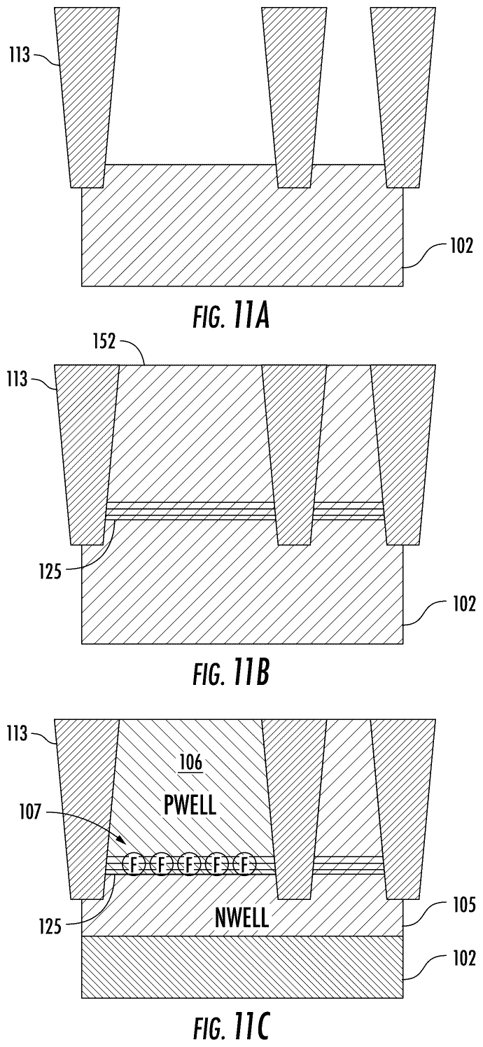

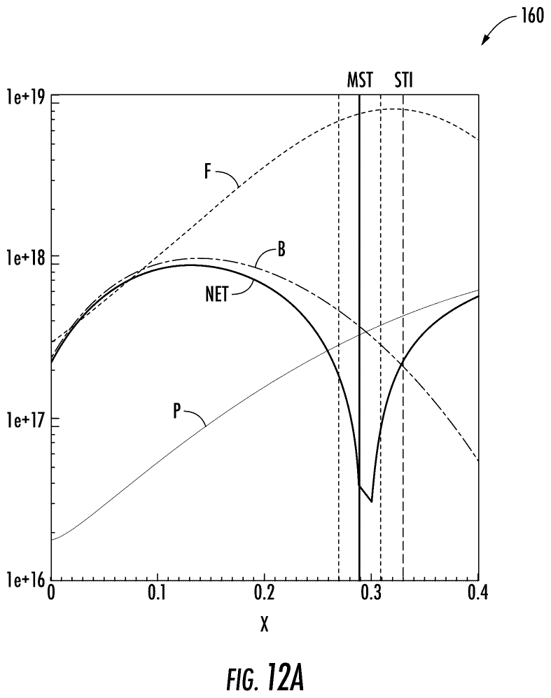

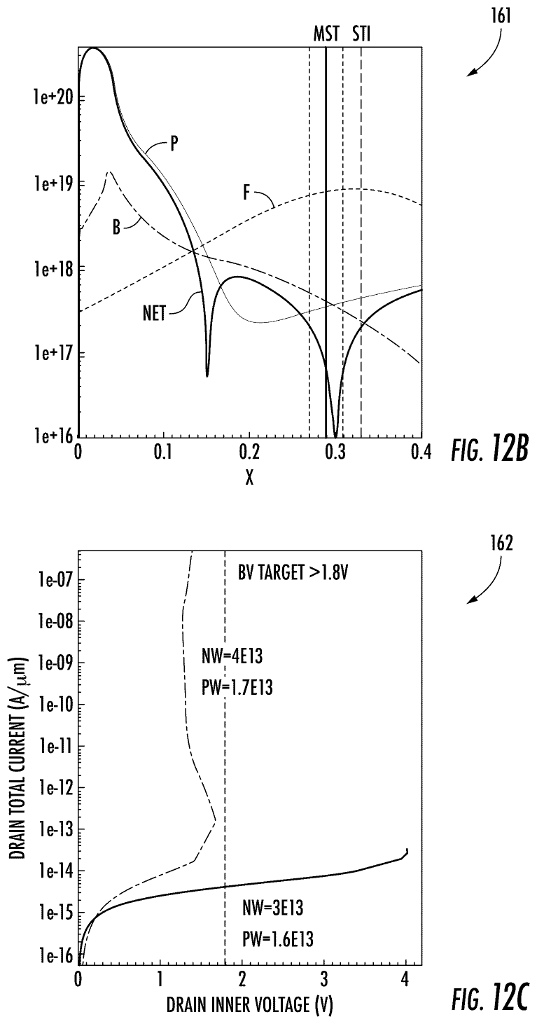

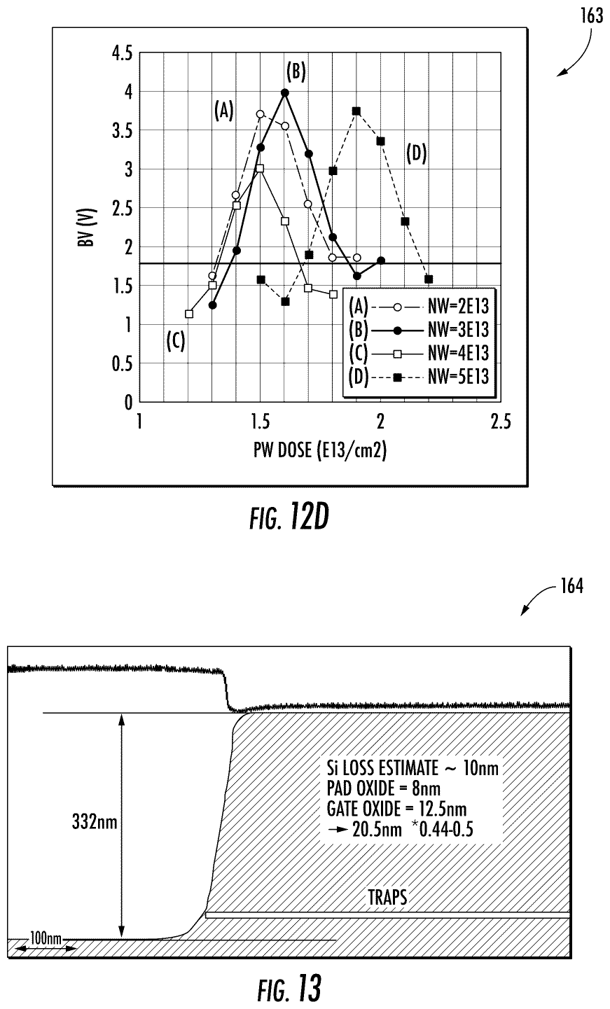

Referring additionally to the graphs 160-163 of FIGS. 12A-12D, example well doping process design considerations for an example 180 nm baseline are now described. For the present implementation, the following example well process sequence was used:
MST Si cap 300 nm (as-grown)
STI module
P 400 keV 3E13/cm2
F 140 keV 2E14/cm2
1050 C 5s RTA
B 35 keV 7E12/cm2
B 60 keV 1.6E13/cm2
1050 C 5s RTA
P 19 keV 2E15/cm2
1050 C 5s RTA
   The resulting doping profile under the channel 110 is shown in the graph 160, while the doping profile under the source/drain regions 108, 109 is shown in the graph 161. The graphs 160, 161 illustrate how the MST-O film advantageously confines/concentrates fluorine atoms at the desired location within the well, i.e., in the depletion layer 107. Furthermore, example drain leakage characteristics are shown in the graph 162, and drain breakdown voltage (BV) vs. NWELL and PWELL dose are shown in the graph 163. A TEM image 164 of a memory cell 100 is provided with example dimensions in FIG. 13, although it will be appreciated that other dimensions may be used in different embodiments.

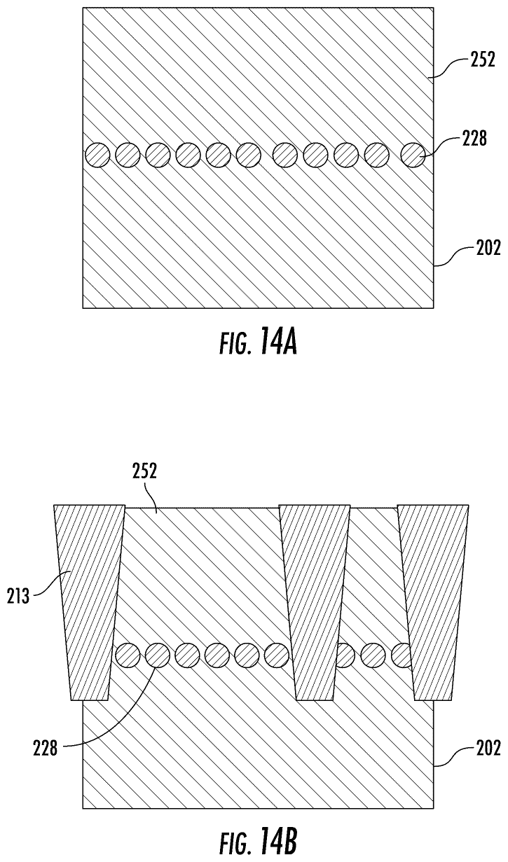

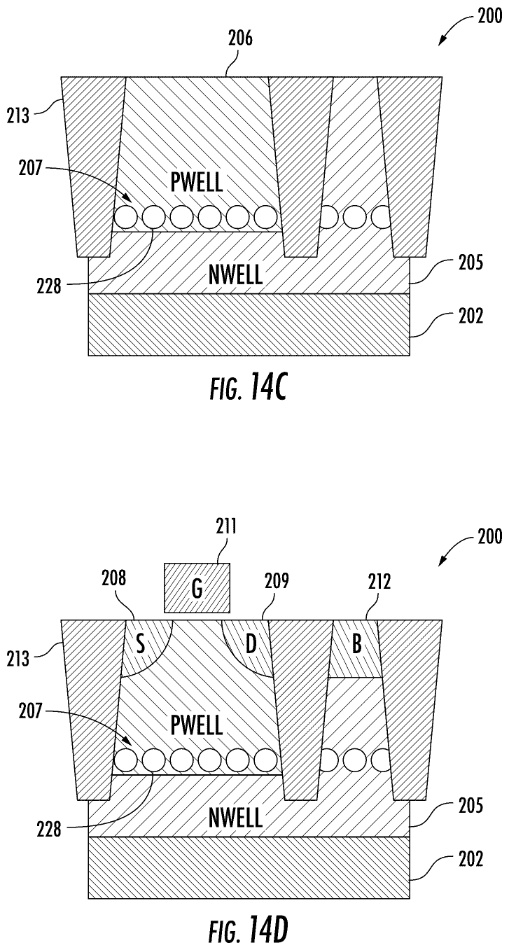

As noted above, the memory cell 100 includes an MST-O layer 125 in the PWELL/NWELL depletion region 107, in which atomic fluorine (or other trap source dopant) is confined at the MST-O layer(s). Turning now to FIGS. 14A-14D, an alternative approach which utilizes an MST layer 225 (see FIG. 16) to fabricate nanocrystals within an NWELL/PWELL depletion region 207 to similarly provide electron/hole trapping is described. More particularly, this approach utilizes the MST film 225 fabrication process to form SiC nanocrystals 228 inside the PWELL/NWELL depletion layer 207.

The process begins with the formation of an MST-C (Si/C) film 225 on a substrate 202, followed by a thick epitaxial cap layer 252, as similarly described above with reference to FIG. 10A. However, at this point a relatively high temperature rapid thermal anneal (RTA), e.g., 1100° C., is performed which causes the SiC nanocrystals 228 to form in place of the MST film 225 (FIG. 14A). The subsequent steps described above of fabricating an NFET in a shallow PWELL surrounded by an NWELL (or vice-versa) may then be performed. More particularly, the STI module may be performed to form STI regions 213 (FIG. 14B), followed by the NWELL 205, fluorine, and PWELL 206 implantations (FIG. 14C). The gate 211, source 208 and drain 209, and body 212 may then be formed, along with associated contacts (not shown), to complete the nonvolatile memory cell 200 (FIG. 14D).

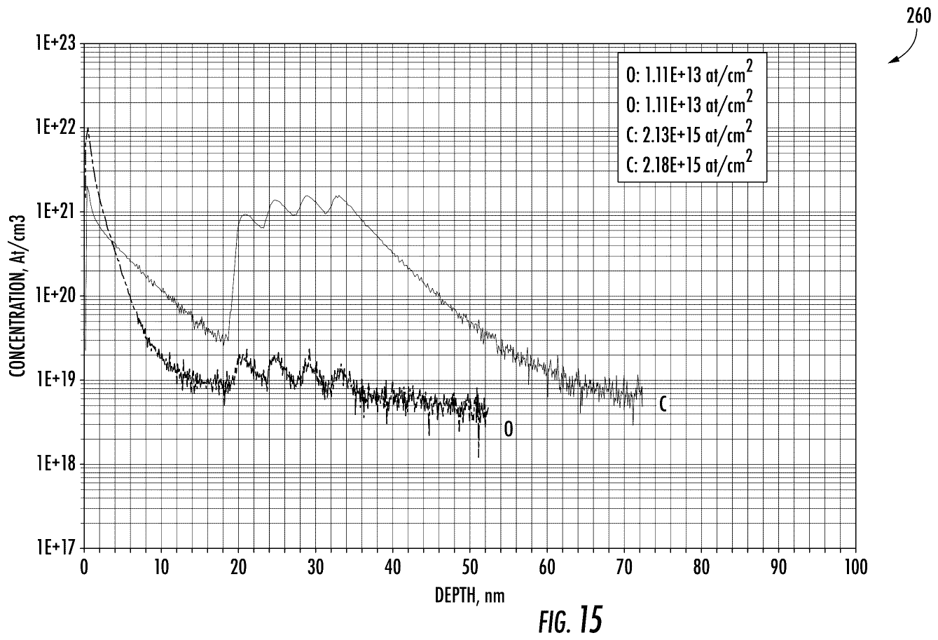

Graph 260 of FIG. 15 provides example carbon dosing times and concentrations for an MST-C film configuration which may be used for SiC nanocrystal formation. Increasing the dose time from 1 second to 3 seconds increases the carbon incorporation to 2.15E15 at/cm². This also increases the value of carbon incorporation to 0.005% by X-Ray, which is ˜2X compared to a 725° C. dose at 1 second with the same carbon level by SIMS.

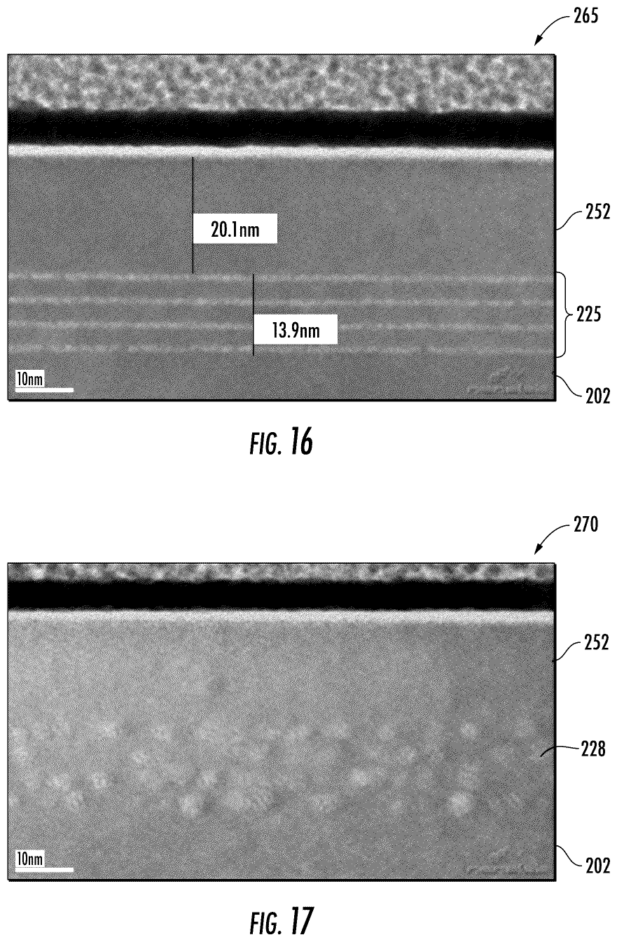

TEM images 265 and 270 of FIGS. 16 and 17 illustrate an example MST-C approach for SiC nanocrystal formation utilizing a two-minute anneal at 1100° C., along with the resulting SiC nanocrystals 228. However, it should be noted that other anneal times and temperatures may be used in different embodiments. For example, anneal times may generally be in a range of about 2-5 minutes, and temperatures may be in a range of about 945° C.-1100° C. in different embodiments. Generally speaking, the transverse optical SiC peak near 800 cm⁻¹ becomes more pronounced with higher anneal temperatures.

Because of the stacked layer structure of the starting superlattice 225 (see FIG. 16), the resulting nanocrystals 228 are similarly constrained within a crystal lattice of adjacent semiconductor portions, just like the original superlattice, as discussed further above. Moreover, because of the atomic layer formation of the carbon atoms, the nanocrystals tend to form laterally spaced apart from one another in vertically spaced apart rows, as seen in FIG. 17.

In summary, programming and erasing of the NVRAM cells 100, 200 described above may advantageously be controlled by injecting electrons and holes via NWELL body bias. More particularly, write operation may be achieved by applying positive reverse bias to the NWELL contact to induce an avalanche breakdown of the PWELL/NWELL junction. Electrons or holes generated by the avalanche breakdown are captured by electron or hole traps in the depletion layer 107 or 207. Erase operations may be achieved by applying negative forward bias to the body contacts 112, 212 to inject holes or electrons to neutralize the trapped electrons or holes. Read operations may be achieved by applying gate 111, 211 and drain 109, 209 bias to the cell transistor.

Many modifications and other embodiments of the invention will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the claims.

1. A memory device comprising:
an array of memory cells on the semiconductor substrate, each memory cell comprising
a first well on the semiconductor substrate having a first conductivity type;
a second well adjacent the first well and having a second conductivity type and defining a depletion layer with the first well;
a superlattice within the depletion layer and comprising
a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions, and
a plurality of trap source atoms within the plurality of stacked groups of layers, the trap source atoms being different than semiconductor atoms of the base semiconductor monolayers and non-semiconductor atoms of the at least one non-semiconductor monolayer;
spaced apart source and drain regions adjacent the second well and defining a channel therebetween; and
a gate overlying the channel.

2. The memory device of claim 1 wherein each memory cell further comprises a body contact region coupled with the first well.

3. The memory device of claim 1 wherein the at least one non-semiconductor monolayer comprises oxygen.

4. The memory device of claim 1 wherein the base semiconductor layers comprise silicon.

5. The memory device of claim 1 wherein the memory cells comprise non-volatile memory cells.

6. The memory device of claim 1 comprising respective shallow trench isolation (STI) regions adjacent the source and drain regions and extending into the first well.

7. The memory device of claim 1 wherein the trap source atoms comprise at least one of fluorine, sulfur, and selenium.

8. The memory device of claim 1 comprising a plurality of word lines and bit lines connecting the array of memory cells.

9. A non-volatile memory device comprising:
a semiconductor substrate;
an array of non-volatile memory cells on the semiconductor substrate, each non-volatile memory cell comprising
a first well on the semiconductor substrate having a first conductivity type;
a body contact region coupled with the first well;
a second well adjacent the first well and having a second conductivity type and defining a depletion layer with the first well;
a superlattice within the depletion layer and comprising
a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions, and
a plurality of trap source atoms within the plurality of stacked groups of layers, the trap source atoms being different than semiconductor atoms of the base semiconductor monolayers and non-semiconductor atoms of the at least one non-semiconductor monolayer;
spaced apart source and drain regions adjacent the second well and defining a channel therebetween; and
a gate overlying the channel.

10. The memory device of claim 9 wherein the at least one non-semiconductor monolayer comprises oxygen.

11. The memory device of claim 9 wherein the base semiconductor layers comprise silicon.

12. The memory device of claim 9 comprising respective shallow trench isolation (STI) regions adjacent the source and drain regions and extending into the first well.

13. The memory device of claim 9 wherein the trap source atoms comprise at least one of fluorine, sulfur, and selenium.

14. The memory device of claim 9 comprising a plurality of word lines and bit lines connecting the array of memory cells.

15. A memory device comprising:
a semiconductor substrate;
an array of memory cells on the semiconductor substrate, each memory cell comprising
a first well on the semiconductor substrate having a first conductivity type;
a second well adjacent the first well and having a second conductivity type and defining a depletion layer with the first well;
a superlattice within the depletion layer and comprising
a plurality of stacked groups of layers, each group of layers comprising a plurality of stacked base silicon monolayers defining a base silicon portion, and at least one oxygen monolayer constrained within a crystal lattice of adjacent base silicon portions, and
a plurality of trap source atoms within the plurality of stacked groups of layers, the trap source atoms being different than semiconductor atoms of the base semiconductor monolayers and non-semiconductor atoms of the at least one non-semiconductor monolayer;
spaced apart source and drain regions adjacent the second well and defining a channel therebetween; and
a gate overlying the channel.

16. The memory device of claim 15 wherein each memory cell further comprises a body contact region coupled with the first well.

17. The memory device of claim 15 wherein the memory cells comprise non-volatile memory cells.

18. The memory device of claim 15 comprising respective shallow trench isolation (STI) regions adjacent the source and drain regions and extending into the first well.

19. The memory device of claim 15 wherein the trap source atoms comprise at least one of fluorine, sulfur, and selenium.

20. The memory device of claim 15 comprising a plurality of word lines and bit lines connecting the array of memory cells.
